(19) United States
(12) Patent Application Publication
(10) Pub. No.: US 2023/0337435 A1
(43) Pub. Date: Oct. 19, 2023

(54) 3D HYBRID MEMORY USING HORIZONTALLY ORIENTED CONDUCTIVE DIELECTRIC CHANNEL REGIONS

(71) Applicant: Tokyo Electron Limited, Tokyo (JP)

(72) Inventors: Mark I. GARDNER, Albany, NY (US); H. Jim FULFORD, Albany, NY (US); Partha MUKHOPADHYAY, Albany, NY (US)

(21) Appl. No.: 18/336,678

(22) Filed: Jun. 16, 2023

Related U.S. Application Data
(63) Continuation-in-part of application No. 17/866,154, filed on Jul. 15, 2022.
(60) Provisional application No. 63/222,868, filed on Jul. 16, 2021.

(51) Int. Cl. H10B 51/20; H10B 51/10; H10B 53/10; H10B 53/20; H01L 29/06; H01L 29/423; H01L 29/786; H01L 29/775; H01L 29/66; H01L 29/417; H01L 21/8234

(52) U.S. Cl. CPC H10B 51/20; H10B 51/10; H10B 53/10; H10B 53/20; H01L 29/0673; H01L 29/42392; H01L 29/7869; H01L 29/78696; H01L 29/775; H01L 29/66439; H01L 29/41733; H01L 21/823412; H01L 21/823418

(57) ABSTRACT

A semiconductor structure includes one or more first nanostructures extending along a first lateral direction; one or more second nanostructures extending along the first lateral direction and vertically disposed above the one or more first nanostructures; and a gate structure extending along a second lateral direction perpendicular to the first lateral direction, and disposed around each of the one or more first nanostructures and each of the one or more second nanostructures. The gate structure comprises: (i) a first metal material, (ii) a ferroelectric material, and (iii) a second metal material.

### CROSS-REFERENCE TO RELATED APPLICATIONS

This application claims the benefit of priority as a continuation-in-part to U.S. patent Ser. No. 17/866,154, filed Jul. 15, 2022, which claims the benefit of and priority to U.S. Provisional Patent Application No. 63/222,868, filed Jul. 16, 2021, entitled “3D Hybrid Memory Using Horizontally Oriented Conductive Dielectric Channel Regions,” the contents of each of which is incorporated by reference in its entirety for all purposes.

### FIELD OF THE DISCLOSURE

This disclosure relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other. 3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (e.g., CPU (central processing unit), GPU (graphics processing unit), FPGA (field programmable gate array, SoC (System on a chip)) is being pursued.

### SUMMARY

The present disclosure relates to non-planar, or 3D, structures and transistors. The channel regions of the transistors may be oriented to conduct current through the channel in a direction generally parallel with the major surface of the system or chip upon which, or within which, these structures are provided. Gate All Around (GAA) structures may be utilized to provide cost, performance, and/or design advantages. The techniques and structures described herein provide a higher density of DRAM using a conductive dielectric channel, which allows for a higher 3D density. In certain implementations, a storage transistor may replace a conventional capacitor, which is typically relatively tall, allowing for a denser and thinner form factor of a DRAM memory array.

One aspect of the present disclosure can be directed to a semiconductor structure. The semiconductor structure may include one or more first nanostructures extending along a first lateral direction; one or more second nanostructures extending along the first lateral direction and vertically disposed above the one or more first nanostructures; and a gate structure extending along a second lateral direction perpendicular to the first lateral direction, and disposed around each of the one or more first nanostructures and each of the one or more second nanostructures. The gate structure comprises: (i) a first metal material, (ii) a ferroelectric material, and (iii) a second metal material.

The one or more first nanostructures and the one or more second nanostructures each include a material selected from the group consisting of: indium oxide (In₂O₃), tin oxide (SnO₂), indium gallium zinc oxide (InGaZnO), zinc oxide (ZnO), tin oxide (SnO), and combinations thereof.

The one or more first nanostructures and the one or more second nanostructures each may include a semiconductor material.

The semiconductor structure may further include a first pair of source/drain structures in contact with the one or more first nanostructures along the first lateral direction; and a second pair of source/drain structures in contact with the one or more second nanostructures along the first lateral direction. In some embodiments, the first pair of source/drain structures are vertically spaced from the second pair of source/drain structures.

The first metal material may include a plurality of first closed-loops surrounding the one or more first nanostructures and the one or more second nanostructures, respectively. In some embodiments, the ferroelectric material includes a plurality of second closed-loops surrounding the first closed-loops, respectively. In some embodiments, the second metal material includes a plurality of third closed-loops surrounding the second closed-loops, respectively.

The gate structure may further comprise a high-k dielectric material interposed between the first metal material and each of the one or more first nanostructures and the one or more second nanostructures. In some embodiments, the one or more first nanostructures, the one or more second nanostructures, the high-k dielectric material, and the first metal material partially operate as a transistor, while the first metal material, the ferroelectric material, and the second metal material operate as a capacitor connected to the transistor in series.

Another aspect of the present disclosure can be directed to a semiconductor structure. The semiconductor structure may include a plurality of first nanostructures extending along a first lateral direction; a plurality of second nanostructures extending along the first lateral direction and vertically disposed above the plurality of first nanostructures; a first gate structure extending along a second lateral direction perpendicular to the first lateral direction, and disposed around each of the plurality of first nanostructures; and a second gate structure extending along the second lateral direction and disposed around each of the plurality of second nanostructures. The first and second gate structures each comprise: (i) a first metal material, (ii) a ferroelectric material, and (iii) a second metal material.

The first and second gate structures may be physically connected to each other.

The first and second gate structures may be physically separated from each other.

The first nanostructures and the second nanostructures each may include a material selected from the group consisting of: indium oxide (In₂O₃), tin oxide (SnO₂), indium gallium zinc oxide (InGaZnO), zinc oxide (ZnO), tin oxide (SnO), and combinations thereof.

The first nanostructures and the second nanostructures each may include semiconductor material.

The first metal material may include a plurality of first closed-loops surrounding the one or more first nanostructures and the one or more second nanostructures, respectively, the ferroelectric material includes a plurality of second closed-loops surrounding the first closed-loops, respectively, and the second metal material includes a plurality of third closed-loops surrounding the second closed-loops, respectively.

The semiconductor structure may further include a first pair of source/drain structures in contact with the first nanostructures along the first lateral direction; and a second pair of source/drain structures in contact with the second nanostructures along the first lateral direction. The first pair of source/drain structures are vertically spaced from the second pair of source/drain structures.

Yet another aspect of the present disclosure may be directed to a method for fabricating semiconductor structures. The method may include forming a plurality of first nanostructures vertically spaced from one another and a plurality of second nanostructures vertically spaced from one another, wherein the plurality of first nanostructures and the plurality of second nanostructures each extend along a first lateral direction; exposing a middle portion of each of the plurality of first nanostructures and the plurality of second nanostructures; and wrapping the exposed middle portion of each of the plurality of first nanostructures and the plurality of second nanostructures with a gate structure. The gate structure comprises: (i) a first metal material, (ii) a ferroelectric material, and (iii) a second metal material.

The method may further include forming a pair of first source/drain structures on opposite ends of the first nanostructures along the first lateral direction and a pair of second source/drain structures on opposite ends of the second nanostructures along the first lateral direction. The pair of first source/drain structures are separated from the pair of second source/drain structures.

The one or more first nanostructures and the one or more second nanostructures each may include a material selected from the group consisting of: indium oxide (In₂O₃), tin oxide (SnO₂), indium gallium zinc oxide (InGaZnO), zinc oxide (ZnO), tin oxide (SnO), and combinations thereof.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise. References to “or” may be construed as inclusive so that any terms described using “or” may indicate any of a single, more than one, and all of the described terms.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a flow chart of a method for making a semiconductor device, in accordance with some embodiments.

FIGS. 2A and 2B illustrate a top view and a cross sectional view of a semiconductor device, respectively, during various fabrication stages, made by the method of FIG. 1, in accordance with some embodiments.

FIGS. 3A and 3B illustrate a top view and a cross sectional view of a semiconductor device, respectively, during various fabrication stages, made by the method of FIG. 1, in accordance with some embodiments.

FIGS. 4A, 4B, and 4C illustrate a top view and two cross-sectional views of a semiconductor device, respectively, during various fabrication stages, made by the method of FIG. 1, in accordance with some embodiments.

FIGS. 5A, 5B, and 5C illustrate a top view and two cross-sectional views of a semiconductor device, respectively, during various fabrication stages, made by the method of FIG. 1, in accordance with some embodiments.

FIGS. 6A, 6B, and 6C illustrate a top view and two cross-sectional views of a semiconductor device, respectively, during various fabrication stages, made by the method of FIG. 1, in accordance with some embodiments.

FIG. 7 illustrates an enlarged cross-sectional view of a semiconductor device, respectively, during various fabrication stages, made by the method of FIG. 1, in accordance with some embodiments.

FIGS. 8A, 8B, and 8C illustrate a top view and two cross-sectional views of another semiconductor device, respectively, during various fabrication stages, made based on the method of FIG. 1, in accordance with some embodiments.

FIGS. 9A, 9B, and 9C illustrate a top view and two cross-sectional views of yet another semiconductor device, respectively, during various fabrication stages, made based on the method of FIG. 1, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more vertical transistor structures having one or more conductive oxide or semiconductor nanostructures formed from nanosheets. In some embodiments, conductive oxide nanostructures formed from conductive oxide nanosheets are formed over epitaxially grown semiconductor nanosheets of said vertical transistor structures. Based on such conductive oxide layers, advantageously, the vertical transistor structures, as disclosed herein, may be associated with a low leakage of a charge stored at a gate. In some aspects, any number of the vertical transistor structures can be laterally (e.g., side-by-side) arranged with each other and vertically stacked on top of one another, thereby forming an array of vertical transistor structures having improved characteristics in an area efficient manner. For example, with two different conductive types of the disclosed transistor structure stacked on top of one another, a complementary field-effect-transistor structure can be formed.

Reference will now be made to the figures, which for the convenience of visualizing the 3D fabrication techniques described herein, illustrate a substrate undergoing a process flow in both top and cross-sectional views. Unless expressly indicated otherwise, each figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections and should not be considered limiting to the scope of the claims.

Likewise, although the figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a rectangular configuration, other shapes are also contemplated, and indeed the techniques described herein may be implemented in any shape or geometry.

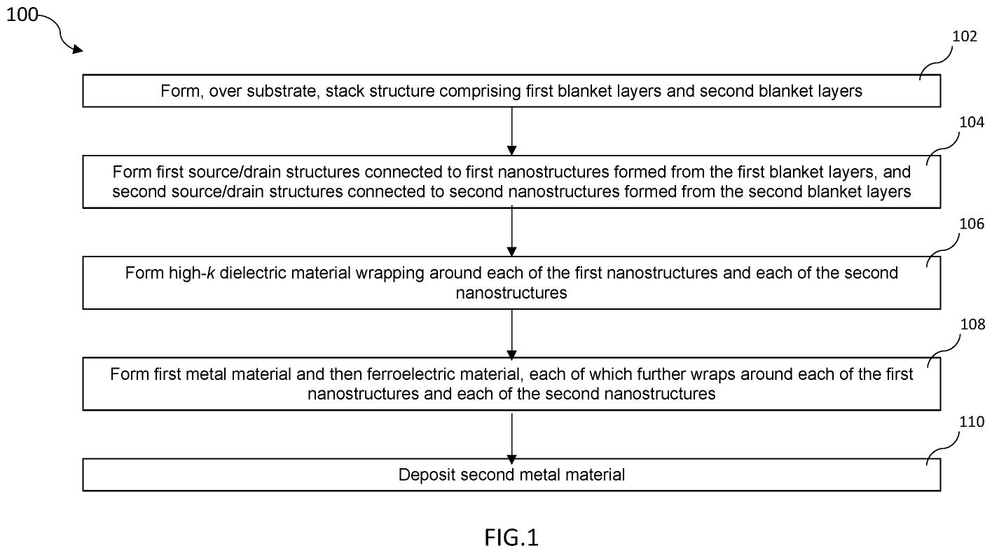

FIG. 1 illustrates a flow chart of a method 100 for making a semiconductor memory device (e.g., one or more transistors), based on a vertical stack structure. For example, the vertical stack structure can be formed by a plurality of nanosheets to form a memory device. The vertical stack structure can include at least one transistor and one or more capacitors connected in series. It is noted that the method 100 is merely an example, and is not intended to limit the present disclosure. Accordingly, it is understood that additional operations may be provided before, during, and after the method 100 of FIG. 1, and that some other operations may only be briefly described herein.

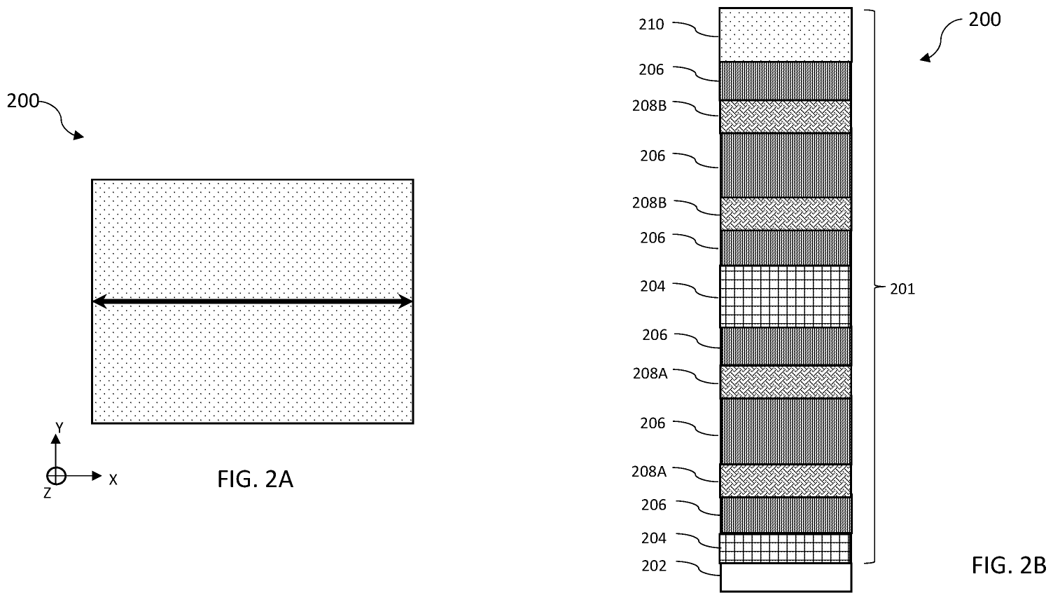

In various embodiments, operations of the method 100 may be associated with top views and cross-sectional views of an example semiconductor device (also referred to herein as a structure) at various fabrication stages as shown in FIGS. 2A to 6A, FIGS. 2B to 6B, FIGS. 4C to 6C, and 7, respectively, which will be discussed in further detail below. It should be understood that the semiconductor device, shown in 2A to 6A, FIGS. 2B to 6B, FIGS. 4C to 6C, and 7, may include a number of other devices such as inductors, fuses, capacitors, coils, etc., while remaining within the scope of the present disclosure.

In brief overview, the method 100 starts with operation 102 of forming, over a substrate, a stack structure comprising a plurality of first blanket layers and a plurality of second blanket layers, in which the first blanket layers and the second blanket layers are vertically separated from each other. The method 100 continues to operation 104 of forming a pair of first source/drain structures connected to first nanostructures formed from the first blanket layers, and a pair of second source/drain structures connected to second nanostructures formed from the second blanket layers. The method 100 proceeds to operation 106 of forming a high-k dielectric material wrapping around each of the first nanostructures and each of the second nanostructures. The method 100 proceeds to operation 108 of forming a first metal material and then a ferroelectric material, each of which further wraps around each of the first nanostructures and each of the second nanostructures. The method 100 proceeds to operation 110 of depositing a second metal material.

Corresponding to operation 102 of FIG. 1, FIG. 2A is a top view of a semiconductor device 200 in which a stack structure 201 including a plurality of first blanket layers 208A and a plurality of second blanket layers 208B is formed over a substrate 202 (e.g., a crystalline silicon, a glass substrate, etc.). FIG. 2B is a corresponding cross-sectional view of the semiconductor device 200 cut along a first lateral direction (e.g., the X-direction), in accordance with various embodiments. The first lateral direction may be the lengthwise or longitudinal direction of a channel of the semiconductor device 200.

In some embodiments of the present disclosure, the first blanket layers 208A and second blanket layers 208B are formed of the same material. For example, the first and second blanket layers 208A-B can include a conductive oxide. The conductive oxide of the first and second blanket layers 208A-B can be doped in the same type. For example, an n-type conductive oxide can include indium oxide (In₂O₃), tin oxide (SnO₂), indium gallium zinc oxide (InGaZnO), zinc oxide (ZnO), combinations thereof, and the like; and a p-type conductive oxide can include tin oxide (SnO) or the like. In another example, the first and second blanket layers 208A-B can include silicon. The silicon of the first and second blanket layers 208A-B can be doped in the same type, e.g., both in n-type or p-type. As will be discussed below, the first and second blanket layers 208A-B can be later formed as respective nanostructures (sometimes referred to as nanosheets) that operatively serve as a channel of one or more gate-all-around (GAA) transistors.

The first and second blanket layers 208A-B may be formed over the substrate 202, with each of the first and second blanket layers 208A-B vertically separated from one another by a corresponding material. For example in FIG. 2B, the first blanket layers 208A are separated by a first set of layers 206, and the second blanket layers 208B are separated by a second set of layers 206. In the example of the first and second blanket layers 208A-B being formed of a conductive oxide, the layers 206 may include a first dielectric material presenting an etching selectivity to the conductive oxide. In the example of the first and second blanket layers 208A-B being formed of silicon, the layers 206 may include silicon-germanium with a first molar ratio.

With the first blanket layers 208A and the second blanket layers 208B vertically separated from each other, the stack structure 201 may further include layers 204 separating the first blanket layers 208A from the substrate 202, and separating the first blanket layers 208A and second blanket layers 208B from each other. In the example of the first and second blanket layers 208A-B being formed of a conductive oxide, the layers 204 may include a second dielectric material presenting an etching selectivity to at least one of the conductive oxide or the first dielectric material of the layers 206. In the example of the first and second blanket layers 208A-B being formed of silicon, the layers 204 may include silicon-germanium with a second molar ratio. The stack structure 201 may further include a dielectric layer 210 formed on the top.

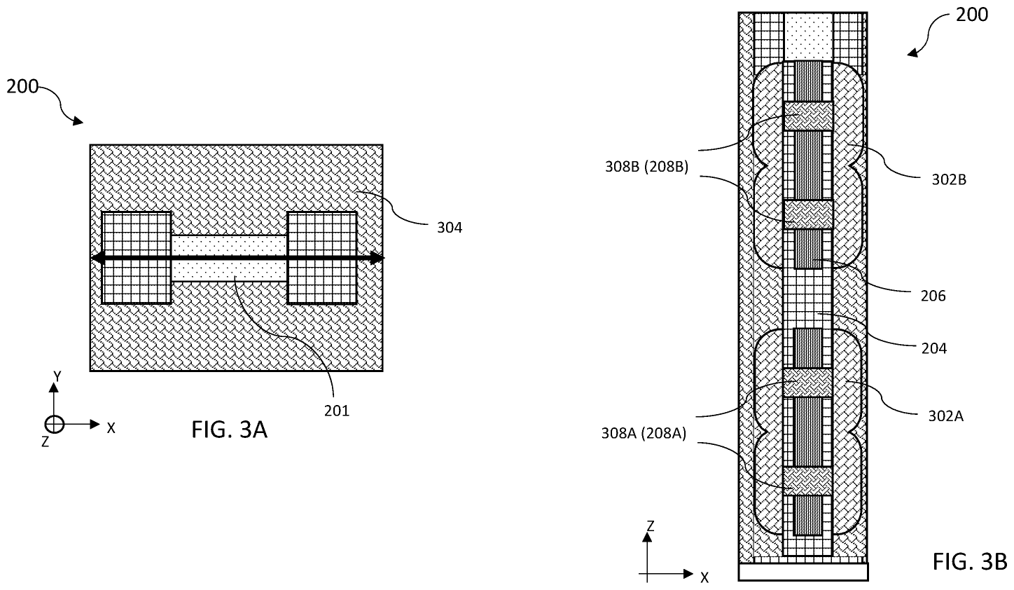

Corresponding to operation 104 of FIG. 1, FIG. 3A is a top view of the semiconductor device 200 in which a pair of first source/drain structures 302A and a pair of second source/drain structures 302B are formed. FIG. 3B is a corresponding cross-sectional view of the semiconductor device 200 cut along a first lateral direction (e.g., the X-direction), in accordance with various embodiments. The first lateral direction may be the lengthwise or longitudinal direction of a channel of the semiconductor device 200.

The first source/drain structures 302A and second source/drain structures 302B are formed of a conductive material (e.g., a metal material), in some embodiments. Further, the first source/drain structures 302A are disposed on opposite sides of first nanostructures 308A along the X-direction and coupled to the first nanostructures 308A, and the second source/drain structures 302B are disposed on opposite sides of second nanostructures 308B along the X-direction and coupled to the second nanostructures 308B, as shown in FIG. 3B. The first nanostructures 308A may be formed from the first blanket layers 208A, and the second nanostructures 308B may be formed from the second blanket layers 208B, which will be discussed as follows.

In some embodiments, the first source/drain structures 302A and second source/drain structures 302B may be formed by performing at least some of the following fabrication steps: defining the stack structure 201 to extend along the X-direction as shown in FIG. 3A (thereby forming the first second nanostructures 308A and second nanostructures 308B); depositing a dielectric material 304 to surround the defined stack structure 201; vertically etching the dielectric material 304 to expose respective ends of the first second nanostructures 308A and second nanostructures 308B; laterally etching end portions of the layers 206 (thereby recessing the layers 206 with respect to the first second nanostructures 308A or second nanostructures 308B); respectively or concurrently forming the first source/drain structures 302A and second source/drain structures 302B; and filling the workpiece with the dielectric material of the layers 204.

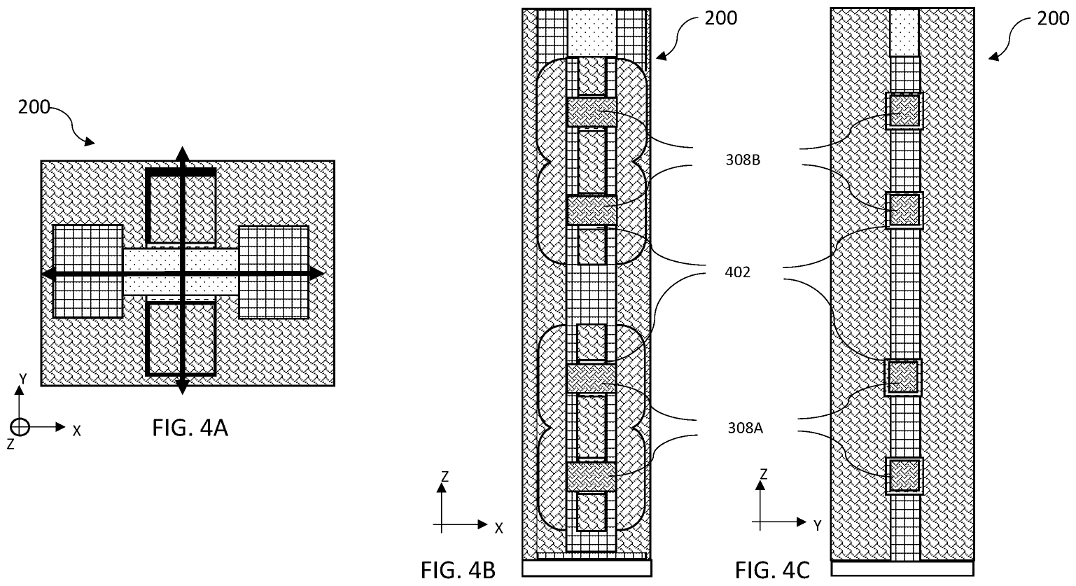

Corresponding to operation 106 of FIG. 1, FIG. 4A is a top view of the semiconductor device 200 in which a high-k dielectric material 402 is formed to wrap around each of the first nanostructures 308A and each of the second nanostructures 308B. FIG. 4B is a corresponding cross-sectional view of the semiconductor device 200 cut along a first lateral direction (e.g., the X-direction) and FIG. 4C is another corresponding cross-sectional view of the semiconductor device 200 cut along a second lateral direction (e.g., the Y-direction), in accordance with various embodiments. The first lateral direction may be the lengthwise or longitudinal direction of a channel of the semiconductor device 200, and the second lateral direction may be the lengthwise or longitudinal direction of a gate structure of the semiconductor device 200.

The high-k dielectric material 402 may be formed as a conformal layer surrounding a circumference of each the first nanostructures 308A and each of the second nanostructures 308B. The high-k dielectric material 402 may include metal oxides, metal nitrides, metal silicates, transition metal-oxides, transition metal-nitrides, transition metal-silicates, oxynitrides of metals, metal aluminates, zirconium silicate, zirconium aluminate, or combinations thereof. Some embodiments may include hafnium oxide (HfO₂), hafnium silicon oxide (HfSiO), hafnium silicon oxynitride (HfSiON), hafnium tantalum oxide (HfTaO), hafnium titanium oxide (HOTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), silicon oxynitrides (SiON), and combinations thereof.

In some embodiments, the high-k dielectric material 402 may be formed by performing at least some of the following fabrication steps: defining the footprint of a gate structure that extends along the Y-direction (as shown in FIG. 4A) by etching at least the dielectric material 304; selectively etching the layers 206 (FIG. 3B) while leaving the first nanostructures 308A and each of the second nanostructures 308B (and other structures/materials) substantially intact (thereby exposing the circumference of each the first nanostructures 308A and each of the second nanostructures 308B); and selectively depositing the high-k dielectric material 402 around the exposed circumferences of the first nanostructures 308A and each of the second nanostructures 308B. As such, the high-k dielectric material 402 can be formed to wrap around each of the first nanostructures 308A and each of the second nanostructures 308B.

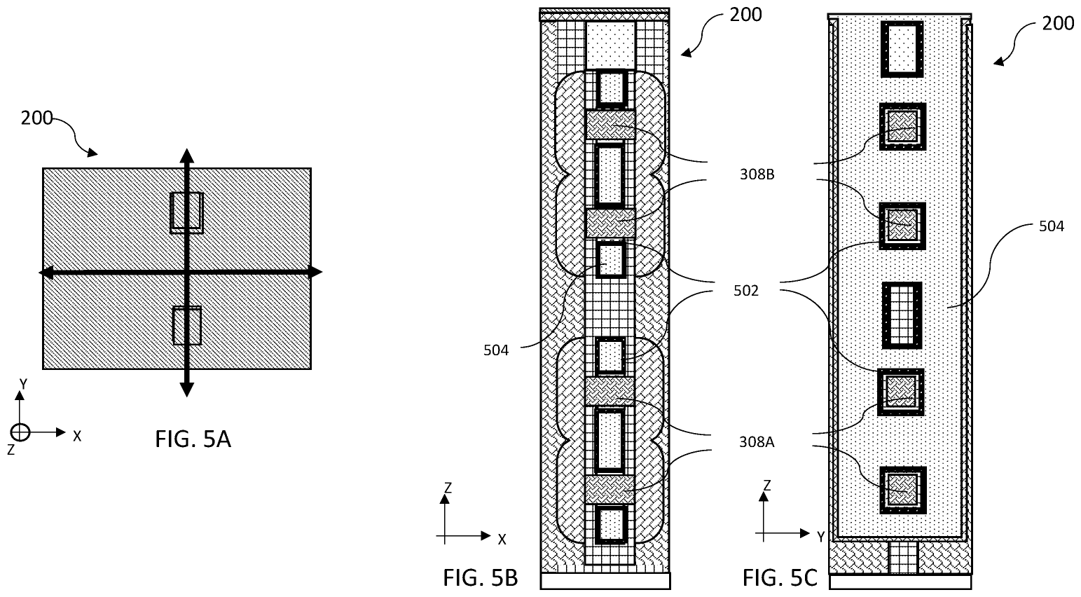

Corresponding to operation 108 of FIG. 1, FIG. 5A is a top view of the semiconductor device 200 in which a first metal material 502 and then a ferroelectric material 504 are formed to further wrap around each of the first nanostructures 308A and each of the second nanostructures 308B. FIG. 5B is a corresponding cross-sectional view of the semiconductor device 200 cut along a first lateral direction (e.g., the X-direction) and FIG. 5C is another corresponding cross-sectional view of the semiconductor device 200 cut along a second lateral direction (e.g., the Y-direction), in accordance with various embodiments. The first lateral direction may be the lengthwise or longitudinal direction of a channel of the semiconductor device 200, and the second lateral direction may be the lengthwise or longitudinal direction of a gate structure of the semiconductor device 200.

The first metal material 502 may be formed as a conformal layer further surrounding the circumference of each the first nanostructures 308A and each of the second nanostructures 308B (i.e., surrounding the high-k dielectric material 402), followed by deposition of the ferroelectric material 504. The first metal material 502 and the ferroelectric material 504 may be non-selectively deposited over the workpiece, in some embodiments. Accordingly, the first metal material 502 can be formed as a plural number of chamber structures that is coupled to one of the first nanostructures 308A/second nanostructures 308B or between adjacent ones of the first nanostructures 308A/second nanostructures 308B. Such chamber-like first metal material 502 are shown as multiple closed-loops in the cross-sectional views of FIGS. 5B-C. Further, the ferroelectric material 504 can be formed to surround an inner surface of each of these chamber-like structures (the first metal material 502), as shown in FIGS. 5B-C.

The first metal material 502 may include copper (Cu), tungsten (W), nickel (Ni), aluminum (Al), tantalum (Ta), titanium (Ti), or any combination thereof. The ferroelectric material 504 may include HfO₂, HfSiOₓ, HfZrOx, Al₂O₃, TiO₂, LaOₓ, BaSrTiOx (BST), PbZrTiOₓ (PZT), or the like, wherein value x is greater than zero and smaller than 1. The ferroelectric material 504 may be formed using PVD, which may be formed at a wafer temperature between about 25° C. and about 400° C.

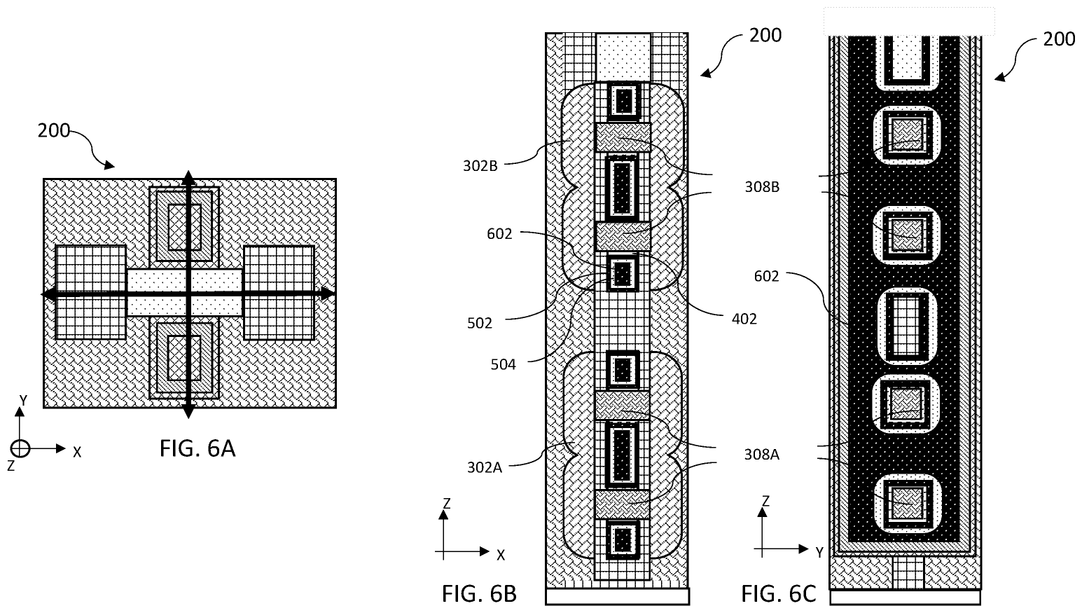

Corresponding to operation 110 of FIG. 1, FIG. 6A is a top view of the semiconductor device 200 in which a second metal material 602 is formed to further wrap around each of the first nanostructures 308A and each of the second nanostructures 308B. FIG. 6B is a corresponding cross-sectional view of the semiconductor device 200 cut along a first lateral direction (e.g., the X-direction) and FIG. 6C is another corresponding cross-sectional view of the semiconductor device 200 cut along a second lateral direction (e.g., the Y-direction), in accordance with various embodiments. The first lateral direction may be the lengthwise or longitudinal direction of a channel of the semiconductor device 200, and the second lateral direction may be the lengthwise or longitudinal direction of a gate structure of the semiconductor device 200.

In some embodiments, the second metal material 602 can be formed to surround an inner surface of each of the chamber-like structures (formed by the ferroelectric material 504), as shown in FIGS. 6B-C. Specifically in FIG. 6B, electrically and physically coupled to each of the first nanostructures 308A and each of the second nanostructures 308B, a multi-layer chamber structure is formed. Such a multi-layer chamber structure may at least consist of the first metal material 502, the ferroelectric material 504, and the second metal material 602, in which the second metal material 602 is formed as a core, with the ferroelectric material 504 surrounding the core, and with the first metal material 502 further surrounding the ferroelectric material 504. The second metal material 602 may include copper (Cu), tungsten (W), nickel (Ni), aluminum (Al), tantalum (Ta), titanium (Ti), or any combination thereof.

In accordance with some embodiments of the present disclosure, upon forming the second metal material 602, a GAA transistor can be formed. For example, the transistor may have a gate structure, a channel, and a pair of source/drain structures. The gate structure may at least consist of the high-k dielectric material 402 and the first metal material 502; the channel may consist of the first nanostructures 308A and the second nanostructures 308B; and the pair of source/drain structures may consist of the source/drain structures 302A and 302B. Stated another way, the first nanostructures 308A and the second nanostructures 308B can collectively serve as a channel of the GAA transistor that is configured to conduct current from one of the source/drain structures 302A or 302B to the other of the source/drain structures 302A or 302B, depending on a gate control of collectively provided by the high-k dielectric material 402 and the first metal material 502.

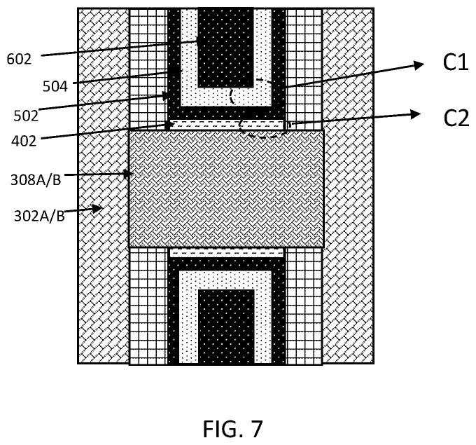

Further, the GAA transistor is electrically coupled to a capacitor in series, where the GAA transistor and the capacitor may form a memory bit cell. The GAA transistor may operatively serve as an access transistor that controls whether the memory cell can be accessed, and the capacitor may operatively serve as a memory portion of the memory cell that is configured to store data. The capacitor can be formed by the first metal material 502, the ferroelectric material 504, and the second metal material 602. As shown in an enlarged view of FIG. 7, in addition to an intrinsic capacitor (C2) formed based on the high-k dielectric material 402, the memory cell, as disclosed herein, further includes a capacitor (C1) formed by the first metal material 502, the ferroelectric material 504, and the second metal material 602. In some embodiments, a capacitive value of the capacitor C1 is at least three times larger than a capacitive value of the capacitor C2, which advantageously enables reliable storage/read operation of the memory cell.

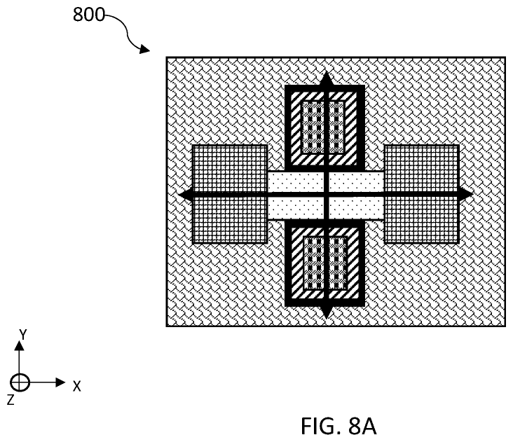

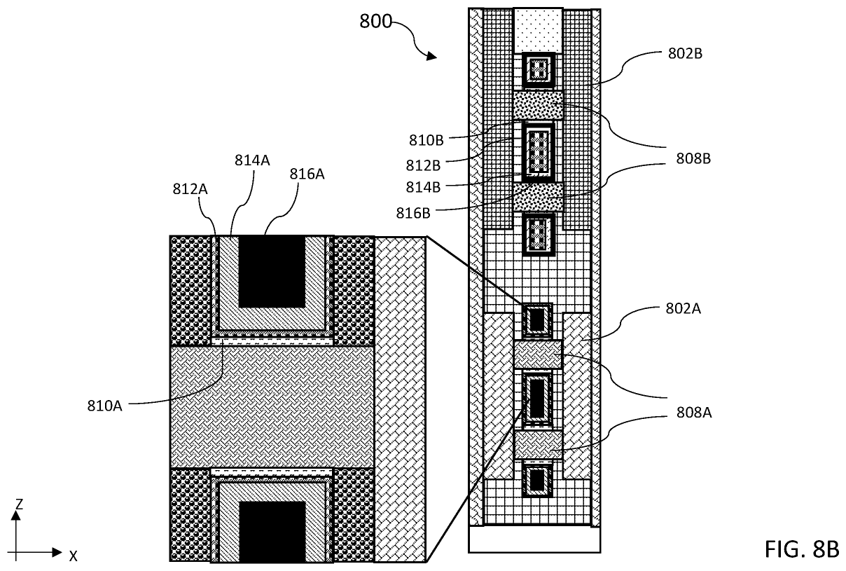

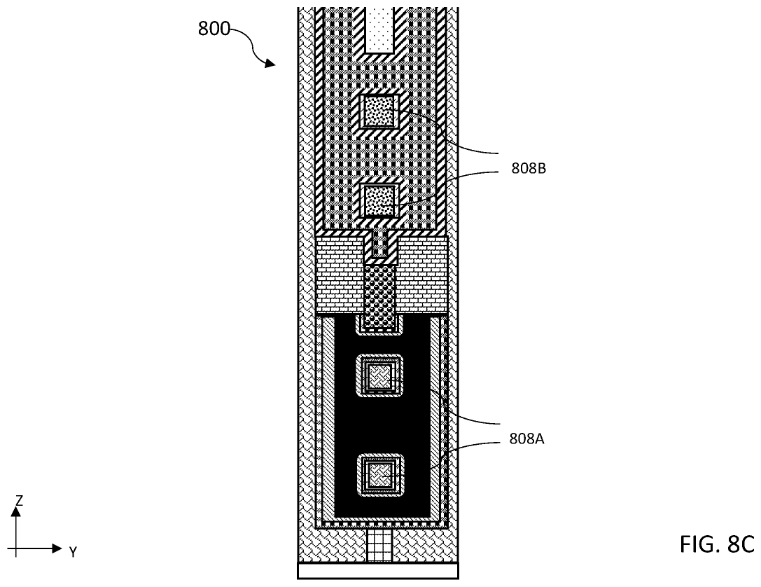

Based on the method 100 of FIG. 1, another semiconductor device the includes two GAA transistors coupled with respectively different capacitors can be formed. FIGS. 8A, 8B, and 8C depict such a semiconductor device 800, in accordance with some embodiments. As shown, the semiconductor device 800 includes first nanostructures 808A and second nanostructures 808B vertically separated from each other, where the first nanostructures 808A are coupled to a pair of first source/drain structures 802A and wrapped by a first gate structure, and the second nanostructures 808B are coupled to a pair of second source/drain structures 802B and wrapped by a second gate structure. The first nanostructures 808A and second nanostructures 808B may include a similar material (e.g., both having a conductive oxide or silicon), but with different conductive types. For example, the first nanostructures 808A may have an n-type conductivity, while the second nanostructures 808B may have a p-type conductivity.

The first gate structure may include a first high-k dielectric material 810A, and a first tri-layer structure: a first metal material 812A, a first ferroelectric material 814A, and a second metal material 816A; and the second gate structure may include a second high-k dielectric material 810B, and a first tri-layer structure: a first metal material 812B, a first ferroelectric material 814B, and a second metal material 816B. Specifically, the first metal material 812A, the first ferroelectric material 814A, and the second metal material 816A can form a plural number of first multi-layer chamber structures, in which the second metal material 816A forms a core, with the first ferroelectric material 814A and the first metal material 812A surrounding the core; and the first metal material 812B, the first ferroelectric material 814B, and the second metal material 816B can form a plural number of second multi-layer chamber structures, in which the second metal material 816B forms a core, with the first ferroelectric material 814B and the first metal material 812B surrounding the core.

In some embodiments, the semiconductor device 800 may be formed by at least some of the operations of the method 100, with certain modification. For example, the first source/drain structures 802A and second source/drain structures 802B, which have respectively different metal materials in some embodiments, may be separately formed. The first high-k dielectric material 810A and second high-k dielectric material 810B may be selectively deposited around the nanostructures 808A and 808B, respectively. Similarly, the first metal materials 812A and 812B may be non-selectively deposited around the nanostructures 808A and 808B, respectively, followed by the respective non-selective deposition of the ferroelectric materials 814A and 814B, and then the respective non-selective deposition of the second metal materials 816A and 816B.

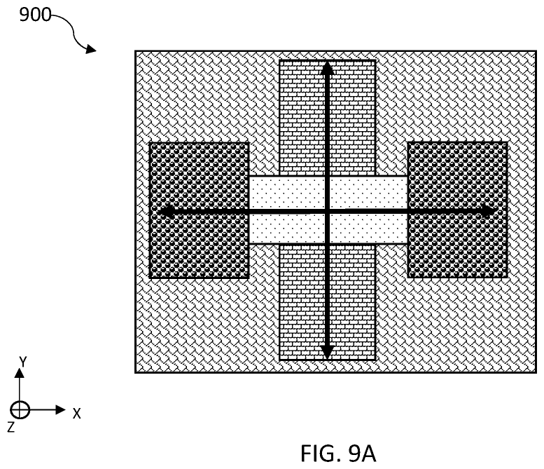

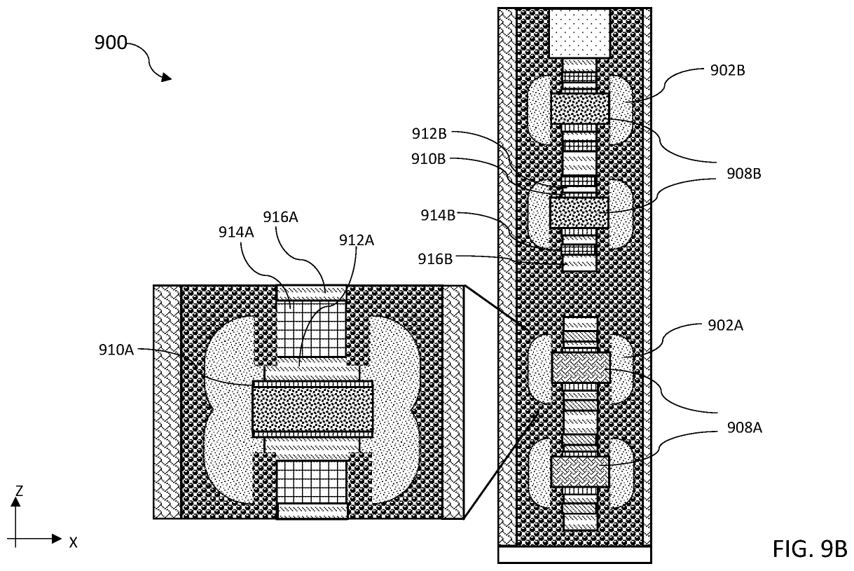

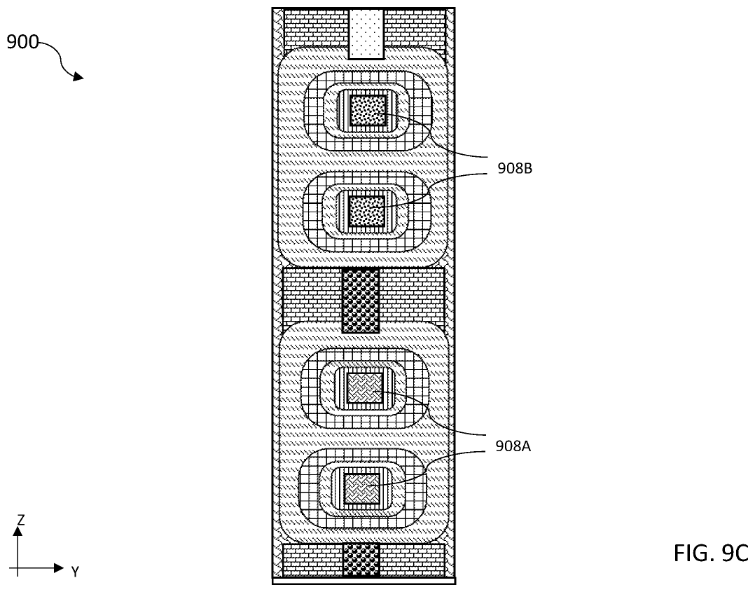

Based on the method 100 of FIG. 1, yet another semiconductor device includes two GAA transistors coupled with respectively different capacitors can be formed. FIGS. 9A, 9B, and 9C depict such a semiconductor device 900, in accordance with some embodiments. As shown, the semiconductor device 900 includes first nanostructures 908A and second nanostructures 908B vertically separated from each other, where the first nanostructures 908A are each coupled to a pair of first source/drain structures 902A and wrapped by a first gate structure, and the second nanostructures 908B are each coupled to a pair of second source/drain structures 902B and wrapped by a second gate structure. The first nanostructures 908A and second nanostructures 908B may include a similar material (e.g., both having a conductive oxide or silicon), but with different conductive types. For example, the first nanostructures 908A may have an n-type conductivity, while the second nanostructures 908B may have a p-type conductivity.

The first gate structure may include a first high-k dielectric material 910A, and a first tri-layer structure: a first metal material 912A, a first ferroelectric material 914A, and a second metal material 916A; and the second gate structure may include a second high-k dielectric material 910B, and a first tri-layer structure: a first metal material 912B, a first ferroelectric material 914B, and a second metal material 916B. Specifically, as shown in the cross-sectional view of FIG. 9B, the first metal material 912A, the first ferroelectric material 914A, and the second metal material 916A can form a first sandwich-like structure, in which the ferroelectric material 914A is interposed between the first metal material 912A and second metal material 916A; and the first metal material 912B, the first ferroelectric material 914B, and the second metal material 916B can form a second sandwich-like structure, in which the ferroelectric material 914B is interposed between the first metal material 912B and second metal material 916B.

In some embodiments, the semiconductor device 900 may be formed by at least some of the operations of the method 100, with certain modification. For example, the first source/drain structures 902A and second source/drain structures 902B, which have respectively different metal materials in some embodiments, may be separately formed. The first high-k dielectric material 910A and second high-k dielectric material 910B may be selectively deposited around the nanostructures 908A and 908B, respectively. Different from the method 100, the first metal materials 912A and 912B may be selectively deposited around the nanostructures 908A and 908B, respectively, followed by the respective selective deposition of the ferroelectric materials 914A and 914B, and then the respective selective deposition of the second metal materials 916A and 916B.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor structure, comprising:
one or more first nanostructures extending along a first lateral direction;
one or more second nanostructures extending along the first lateral direction and vertically disposed above the one or more first nanostructures; and
a gate structure extending along a second lateral direction perpendicular to the first lateral direction, and disposed around each of the one or more first nanostructures and each of the one or more second nanostructures,
wherein the gate structure comprises: (i) a first metal material, (ii) a ferroelectric material, and (iii) a second metal material.

2. The semiconductor structure of claim 1, wherein the one or more first nanostructures and the one or more second nanostructures each include a material selected from the group consisting of: indium oxide (In₂O₃), tin oxide (SnO₂), indium gallium zinc oxide (InGaZnO), zinc oxide (ZnO), tin oxide (SnO), and combinations thereof.

3. The semiconductor structure of claim 1, wherein the one or more first nanostructures and the one or more second nanostructures each include a semiconductor material.

4. The semiconductor structure of claim 1, further comprising:
a first pair of source/drain structures in contact with the one or more first nanostructures along the first lateral direction; and
a second pair of source/drain structures in contact with the one or more second nanostructures along the first lateral direction.

5. The semiconductor structure of claim 4, wherein the first pair of source/drain structures are vertically spaced from the second pair of source/drain structures.

6. The semiconductor structure of claim 1, wherein the first metal material includes a plurality of first closed-loops surrounding the one or more first nanostructures and the one or more second nanostructures, respectively.

7. The semiconductor structure of claim 6, wherein the ferroelectric material includes a plurality of second closed-loops surrounding the first closed-loops, respectively.

8. The semiconductor structure of claim 7, wherein the second metal material includes a plurality of third closed-loops surrounding the second closed-loops, respectively.

9. The semiconductor structure of claim 1, wherein the gate structure further comprises a high-k dielectric material interposed between the first metal material and each of the one or more first nanostructures and the one or more second nanostructures.

10. The semiconductor structure of claim 9, wherein the one or more first nanostructures, the one or more second nanostructures, the high-k dielectric material, and the first metal material partially operate as a transistor, while the first metal material, the ferroelectric material, and the second metal material operate as a capacitor connected to the transistor in series.

11. A semiconductor structure, comprising:
a plurality of first nanostructures extending along a first lateral direction;
a plurality of second nanostructures extending along the first lateral direction and vertically disposed above the plurality of first nanostructures;
a first gate structure extending along a second lateral direction perpendicular to the first lateral direction, and disposed around each of the plurality of first nanostructures; and
a second gate structure extending along the second lateral direction and disposed around each of the plurality of second nanostructures,
wherein the first and second gate structures each comprise: (i) a first metal material, (ii) a ferroelectric material, and (iii) a second metal material.

12. The semiconductor structure of claim 11, wherein the first and second gate structures are physically connected to each other.

13. The semiconductor structure of claim 11, wherein the first and second gate structures are physically separated from each other.

14. The semiconductor structure of claim 11, wherein the first nanostructures and the second nanostructures each include a material selected from the group consisting of: indium oxide (In₂O₃), tin oxide (SnO₂), indium gallium zinc oxide (InGaZnO), zinc oxide (ZnO), tin oxide (SnO), and combinations thereof.

15. The semiconductor structure of claim 11, wherein the first nanostructures and the second nanostructures each include semiconductor material.

16. The semiconductor structure of claim 11, wherein the first metal material includes a plurality of first closed-loops surrounding the one or more first nanostructures and the one or more second nanostructures, respectively, the ferroelectric material includes a plurality of second closed-loops surrounding the first closed-loops, respectively, and the second metal material includes a plurality of third closed-loops surrounding the second closed-loops, respectively.

17. The semiconductor structure of claim 11, further comprising:
a first pair of source/drain structures in contact with the first nanostructures along the first lateral direction; and
a second pair of source/drain structures in contact with the second nanostructures along the first lateral direction;
wherein the first pair of source/drain structures are vertically spaced from the second pair of source/drain structures.

18. A method for fabricating semiconductor structures, comprising:
forming a plurality of first nanostructures vertically spaced from one another and a plurality of second nanostructures vertically spaced from one another, wherein the plurality of first nanostructures and the plurality of second nanostructures each extend along a first lateral direction;
exposing a middle portion of each of the plurality of first nanostructures and the plurality of second nanostructures; and
wrapping the exposed middle portion of each of the plurality of first nanostructures and the plurality of second nanostructures with a gate structure,
wherein the gate structure comprises: (i) a first metal material, (ii) a ferroelectric material, and (iii) a second metal material.

19. The method of claim 18, further comprising:
forming a pair of first source/drain structures on opposite ends of the first nanostructures along the first lateral direction and a pair of second source/drain structures on opposite ends of the second nanostructures along the first lateral direction;
wherein the pair of first source/drain structures are separated from the pair of second source/drain structures.

20. The method of claim 18, wherein the one or more first nanostructures and the one or more second nanostructures each include a material selected from the group consisting of: indium oxide (In₂O₃), tin oxide (SnO₂), indium gallium zinc oxide (InGaZnO), zinc oxide (ZnO), tin oxide (SnO), and combinations thereof.
